(19) United States
(12) Patent Application Publication
(10) Pub. No.: US 2005/0111577 A1
(43) Pub. Date: May 26, 2005

(54) Method for residual carrier suppression in an arrangement which has a vector modulator

(76) Inventor: Stephan Fuchs, Mering (DE)

Correspondence Address: ESCHWEILER & ASSOCIATES, LLC;NATIONAL CITY BANK BUILDING, 629 EUCLID AVE., SUITE 1210, CLEVELAND, OH, 44114, US

(21) Appl. No.: 10/940,116

(22) Filed: Sep. 14, 2004

(30) Foreign Application Priority Data
Sep. 15, 2003 (DE) DE 103 42 583.7

(51) Int. Cl. H03K 5/159

(52) U.S. Cl. 375/298; 375/261

(57) ABSTRACT

In a method for residual carrier suppression, in which a vector modulator is used to convert a baseband signal, which comprises an in-phase component and a quadrature component, to a complex output signal, one component of the baseband signal is supplied as a constant signal with a first polarity during a first time period, and a first average power of the output signal is determined. The component is then supplied as a constant signal with a second polarity during a second time period, and a second average power is determined. The DC signal element of the component of the baseband signal is calculated by forming the difference between the first and the second power of the output signal. The value determined in this way may be added to or subtracted from the component of the baseband signal as a constant signal, in order in this way to compensate for a DC signal. The residual carrier is thus suppressed.

### REFERENCE TO RELATED APPLICATIONS

This application claims the benefit of the priority date of German application DE 103 42 583.7, filed on Sep. 15, 2003, the contents of which are herein incorporated by reference in their entirety.

### FIELD OF THE INVENTION

The invention relates to a method for residual carrier suppression in an arrangement which has a vector modulator, in which the vector modulator is designed to convert a baseband signal, which comprises an in-phase component and a quadrature component, to a complex output signal.

### BACKGROUND OF THE INVENTION

Vector modulators are an important component of modern communication appliances for mobile radio. A vector modulator in this case converts a so-called baseband signal with the aid of a local oscillator, and emits a corresponding output signal at a specific frequency. The baseband signal in this case comprises two components, an in-phase component (I) and a quadrature component (Q). The two components of the baseband signal are converted, in one mixer in each case, using a local oscillator signal, which adds converted signals and outputs them as a complex RF signal. The two local oscillator signals which are used for the vector modulator mixers in this case have a phase offset of 90°. This likewise results in a phase offset of 90° between the two components for the converted in-phase component and the converted quadrature component. This is therefore also referred to as complex modulation.

One example of a vector modulator, which is also referred to as an IQ modulator or IQ mixer, is described in “Tietze, Schenk, Halbleiterschaltungstechnik” [Semiconductor circuit technology], 12^{th} Edition, page 1474.

However, in an actual embodiment, interference signals are also present in addition to the desired signals at the inputs of the vector modulator mixers, and these lead to an undesirable sideband as well as a residual carrier in the spectrum of the output signal from the vector modulator. Prior art FIG. 2A shows an ideal spectrum of an output signal from a vector modulator, where a sine-wave baseband signal at a frequency of 300 kHz has been converted by means of a local oscillator signal to a frequency of 1.88 GHz. The input signal in prior art FIG. 2B contains various interference components. These lead on the one hand to a residual carrier at 1.88 GHz, which is only about 23 dB below the desired signal, and to an undesirable sideband which is suppressed by about 33 dB. The primary reason for the residual carrier is the DC current and voltage components in the in-phase and quadrature components of the baseband signal. The DC parts of the components of the baseband signal are created throughout the entire chain of the baseband signal processing, and are often caused by leakage currents in active components. However, DC current and DC voltage components also occur at the local oscillator input of the two mixers in the vector modulator.

Since a strong residual carrier leads to the signal quality becoming considerably worse, this is frequently calibrated, and is compensated for, by means of a complex method in production. One calibration option is to supply a sine-wave signal as an in-phase component and quadrature component, respectively, to the vector modulator and to the entire baseband signal processing chain, respectively. The spectrum of the converted signal is determined, and the residual carrier is determined. A DC signal is then added to or subtracted from the component to be calibrated on an adaptive basis, until the maximum residual carrier suppression is achieved. However, a method such as this is highly time-consuming, since the associated routine has to be repeated several times.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

The invention provides methods for residual carrier suppression in an arrangement which has a vector modulator, which methods can be implemented relatively quickly and using relatively simple means.

In accordance with an aspect of the invention, an arrangement which has a vector modulator is supplied with one of the components of the baseband signal as a signal at a constant level, and with a first polarity in a first time period, and a first average signal amplitude or a first average power of the output signal is determined. In a second step, one of the components of the baseband signal is supplied as a signal at a constant level and with a second polarity in a second time period, and a second average signal amplitude or a second average power of the output signal is determined. A first and a second signal, which are constant in places, are thus applied, and the power during these time periods is determined and/or measured. Finally, an offset value for the component of the baseband signal is determined by forming the difference between the determined first and second average signal amplitude or power. This offset corresponds to the undesirable DC signal element of the baseband signal component.

This aspect therefore makes it possible to obtain the DC signal offset of the component of the baseband signal in only two steps, specifically two measurements of the average signal amplitude of the output signal. In order to suppress the residual carrier, the determined offset value of the component of the baseband signal is added to or subtracted from the component of the baseband signal as a signal at a constant level. This compensates for the DC signal element of the component of the baseband signal. The method is expediently carried out separately both for the in-phase component and for the quadrature component of the baseband signal. The two determined offset values are added to and subtracted from the respective components. The method can be carried out extremely quickly. Since, furthermore, there are no further signal components in the output signal apart from the residual carrier, the signal amplitude or the power of the residual carrier can be determined using particularly simple means.

In another aspect of the invention, the determination of the offset value comprises multiplication of the value of the difference between the first and second signal amplitude by the reciprocal of the sum of the first and second signal amplitudes. Thus, in order to determine the offset value, the difference between the first and second signal amplitudes is divided by the sum of the first and second signal amplitudes. This ratio also has to be multiplied by a proportionality factor, which takes account of any gain in the output signal by means of the vector modulator or an amplifier stage connected downstream from the vector modulator.

In yet another aspect of the invention, a method is carried out with two or more signals. The signals have different amplitudes to one another, which are constant in places. It is thus possible to determine an offset value as a function of the amplitude of the constant signal. A method such as this is particularly advantageous when the DC signal elements in the in-phase and quadrature components of the baseband signal have a non-linear profile and are dependent on the amplitudes of the components of the baseband signal. An offset value can thus be determined for every possible input amplitude of an in-phase or quadrature component of the baseband signal.

In another aspect, a method is carried out both for the in-phase component and for the quadrature component of the baseband signal, and an offset between the in-phase component and the quadrature component is also determined.

This is done by determining the quotient of the sum of the first and second signal amplitudes of an output signal of one component, divided by the sum of the first and second signal amplitudes of the output signal from the other component. The method according to the invention therefore not only makes it possible to compensate for DC signal elements in the in-phase and quadrature components, but also for a different gain between the in-phase component and quadrature component.

In a further aspect of the invention, the signal which is used is a difference signal. The method is then carried out with a difference signal at a constant level. The difference signal has two signal components, of opposite polarity. This is expedient whenever the vector modulator in which the method is carried out is designed for difference signal processing.

It is particularly expedient for the first and second signal amplitudes of the output signal to be determined by means of a power measurement. This is expedient when the average power of the output signal is being determined. Furthermore, a power measurement can be carried out with simple means and particularly quickly.

In one aspect according to the invention, a spectrum analyzer or a network analyzer is used for determination of the signal amplitude of the output signal. This is advantageous since a spectrum analyzer has high frequency selectivity. If this is not necessary, a power measurement device or a diode may be used as an alternative for determination of the signal amplitude of the output signal from the vector modulator. A diode is particularly advantageous when the method is also intended to be carried out within an arrangement without any additional external test layout.

### BRIEF DESCRIPTION OF THE DRAWINGS

The invention will be explained in detail in the following text with the assistance of the drawing, in which:

FIGS. 1A to 1C show I/Q state diagrams in order to explain interference signals,

FIGS. 2A to 2B show a spectrum for an ideal signal and for a signal subject to interference,

FIG. 3 shows a voltage/time diagram of one component of the baseband signal,

FIG. 4 shows a voltage/time diagram of the calibration signals used for the method according to the invention,

FIG. 5 shows a voltage/time diagram for the output signal for the method,

FIG. 6 shows a spectrum of an output signal based on the method that is used, and

FIG. 7 shows a block diagram with devices for carrying out the method.

### DETAILED DESCRIPTION OF THE INVENTION

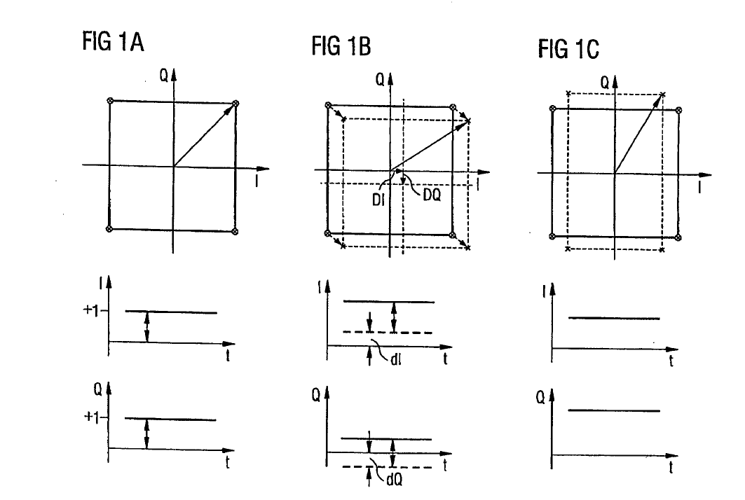

FIG. 1A shows an I/Q state diagram with ideal I and Q components. The abscissa of the diagram represents the in-phase component I, and the ordinate represents the quadrature component Q. This illustration also shows the in-phase component I as the real part of the baseband signal, and the quadrature component Q as the imaginary part of the baseband signal.

The four points on the I/Q plane represent the possible states of the I and Q signals for one specific type of modulation, which is referred to as QPSK modulation. Thus, by way of example, the point which is identified by the arrow on the I/Q plane can be reached by using a positive signal with the amplitude +1 for the in-phase component I and a positive signal with the amplitude +1 for the quadrature component Q. In this specific application, signals which vary over time are used as the in-phase component and quadrature component of the baseband signal. These signals which vary over time can be expressed by means of cosine and sine functions. Mathematically, the output signal from an ideal vector modulator can thus be described by the formula:
uₛ(t)=cos(ω_{c}t)*cos(ω_{mod}t+φ_{T})+sin(ω_{c}t)*sin(ω_{mod}t+φ_{T}) (1)

The expression uₛ (t) in this case indicates the voltage of the output signal over time, ω_{c} denotes the carrier frequency, ω_{mod} denotes the modulation frequency of the signal (which varies over time) of the in-phase and quadrature components, and φ_{T} denotes a phase offset that is present.

FIG. 1B shows the I/Q plane, with a DC signal element being applied to the in-phase and quadrature components of the baseband signal. This leads to a shift in the I/Q plane, thus resulting in a plane which is indicated by the dashed line. The in-phase component is shifted by the DC signal element dI in the positive direction. This results in a somewhat larger value as the sum of the overall signal I. The quadrature component has a DC signal element dQ in the negative direction. Thus, in the illustrated example, the total amplitude of the quadrature component is reduced by the value of the DC signal element dQ. This process is likewise indicated by the drawings underneath this, of the components plotted against the time t. The positive DC signal element means that the amplitude of the real component I plotted against the time t is somewhat greater, while that of Q is somewhat less.

FIG. 1C shows an I/Q plane in which the in-phase component and the quadrature component have different gain levels. While the amplitude of the two components is the same in the ideal case shown in FIG. 1A, distortion between the in-phase component and quadrature component can be seen in the FIG. 1C, which is also referred to as “IQ imbalance”. This is caused, for example, by a different internal gain in the baseband signal processing and/or in the vector modulator mixers. The different gain results in the real signal amplitude I being reduced somewhat, while the amplitude of the quadrature component Q rises at the same time.

The distortion which is shown in FIGS. 1B and 1C can be expressed in the above formula by the addition of DC elements. For a real system, that is to say a system which has distortion, matching errors and undesirable DC signal elements, the voltage of the output signal from the vector modulator is given by the formula:
uₛ(t)=cos(ω_{c}t)*[I_{DC}+cos(ω_{mod}t+φ_{T})]+sin(ω_{c}t)*[Q_{DC}+IQ_{AMP}*sin(ω_{mod}t+φ_{T}+φᵢₘₚₐᵢᵣ)] (2)

In this case, I_{DC} and Q_{DC} denote the undesirable DC signal elements in the in-phase component and quadrature component of the baseband signal. The element IQ_{AMP} describes the different gain levels of the in-phase component and quadrature component as shown in figure element C. The phase φᵢₘₚₐᵢᵣ indicates a phase offset between the in-phase component and the quadrature component, although this is not considered in the following text.

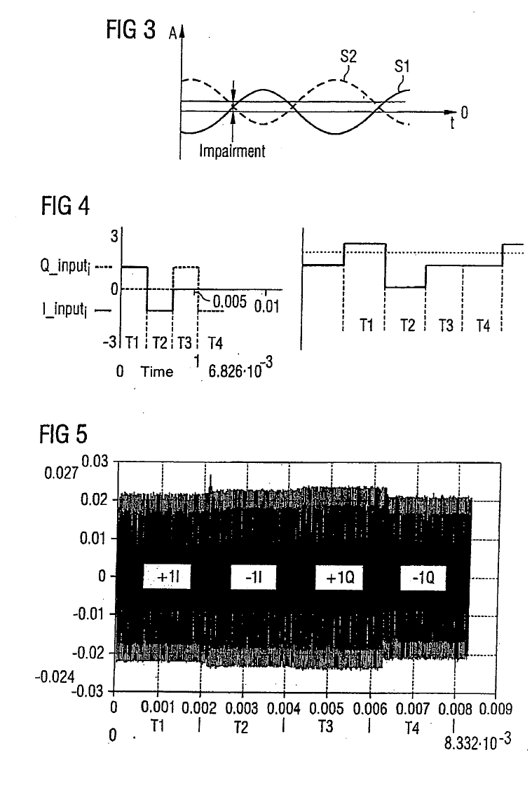

By way of example, an offset caused by a DC signal element is shown on a sine-wave signal in FIG. 3. The curves S1 and S2 are in each case offset in phase through 180°, which corresponds to multiplication by a factor of −1. In the figure, the curve S2 has been shifted with respect to the curve S1. This is caused by a DC signal element, which in one case is added to the sine-wave curve, and in the other case is subtracted from it. The offset voltage U_{DC} is defined as:

$${U}_{DC} = \frac{{U}_{BB} ( t ) - {U}_{BB -} ( t )}{2} \qquad ( 3 )$$

The two applied signals U_{BB} and U_{BB-} in this case have the same magnitudes, which have a different mathematical sign.

In order to compensate for the DC signal elements in the baseband, the constant signals shown in FIG. 4 are applied to the I and Q inputs of the arrangement. The signal at the input for the in-phase component of the vector modulator has a positive amplitude with a constant amplitude magnitude, for example +1, throughout a first time period T1. It is consequently constant in this time period. No signal is applied at the same time for the input for the quadrature component. A signal with the same amplitude magnitude, but with the opposite mathematical sign is applied to the signal input for the in-phase component throughout the time period T2. In the exemplary embodiment, this is the amplitude −1, which is constant in places, for the in-phase component. Furthermore, no signal is applied to the input for the quadrature component. The signal at the I input for the in-phase component of the vector modulator is switched off throughout the time periods T3 and T4, and the signal for the quadrature component has a positive constant amplitude throughout the time period T3, while it has a negative constant amplitude throughout the time period T4. The amplitudes of the in-phase component and quadrature component are once again of the same magnitude, but have different mathematical signs.

The output signal from the vector modulator is shown, plotted against time, in FIG. 5. A considerable difference can be seen between the signals in these time periods T1 and T2 and between the signals in the time periods T3 and T4. The average output level is approximately constant within each time period. The amplitude of the output signal is slightly different, owing to an undesirable signal element in the in-phase component. The DC signal element is subtracted from the input signal in the first time period T1, while it is added to the applied in-phase component I in T2. As can be seen, the DC signal element has a negative mathematical sign for the in-phase component in this example.

A DC signal element is added to the component in the third time period T3, in which a signal +1 is applied to the quadrature component, and the DC signal element is subtracted in the fourth time period. This results in a signal element with a positive mathematical sign.

The DC signal element is calculated by measurement of the signal power during the time periods T1, T2, T3 and T4. The DC signal element in one component of the baseband signal is then determined using the formula:

$${U}_{IMPAIR} = {U}_{AMPL} * \frac{( {U}_{RMS\_Tx} - {U}_{RMS\_Ty} )}{( {U}_{RMS\_Tx} + {U}_{RMS\_Ty} )} \qquad ( 4 )$$

In this case, the measured average power during the time periods T1, T2 as well as T3 and T4, respectively, is used for U_{RMSTx} and URMST_{Y}, respectively. The value U_{AMPL} is a proportionality factor which is required in this specific embodiment in order to take account of amplifiers or attenuators connected downstream from the vector modulator. The DC signal element in the in-phase component is calculated in this exemplary embodiment from the average power throughout the time periods T1 and T2, while the average power during the time periods T3 and T4 is used for the DC signal element in the quadrature component. Compensation is carried out by subtracting the offset value determined in this way, as a constant signal, from the applied I or Q signal, respectively. In the exemplary embodiment, this results in an offset value of about −0.034U_{AMPL} for the in-phase component, and an offset value of about +0.073U_{AMPL} for the quadrature component.

Furthermore, the measurement of the power of the in-phase component and quadrature component for respectively opposite signals also makes it possible to calculate the ratio of the gain Rap between the in-phase component and the quadrature component of the baseband signal, and thus to compensate for it, if necessary. This is done by using the ratio of the sums of the average power levels during the time periods T3 and T4, as well as T1 and T2, thus resulting in the mathematical formula:

$${R}_{AMP} = \frac{( {U}_{RMS\_T3} + {U}_{RMS\_T4} )}{( {U}_{RMS\_T1} + {U}_{RMS\_T2} )} \qquad ( 5 )$$

In this case, the ratio calculated in this way is used to multiply the signals for the in-phase component by the corresponding value R_{AMP}.

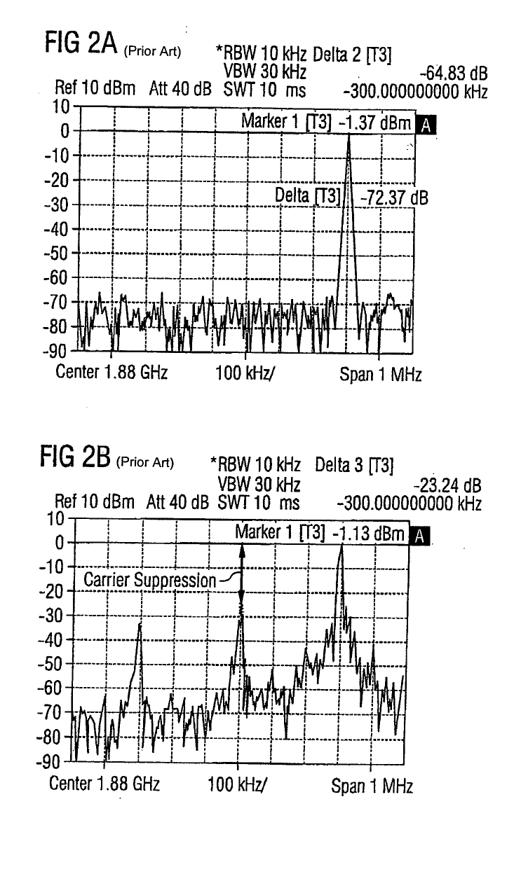

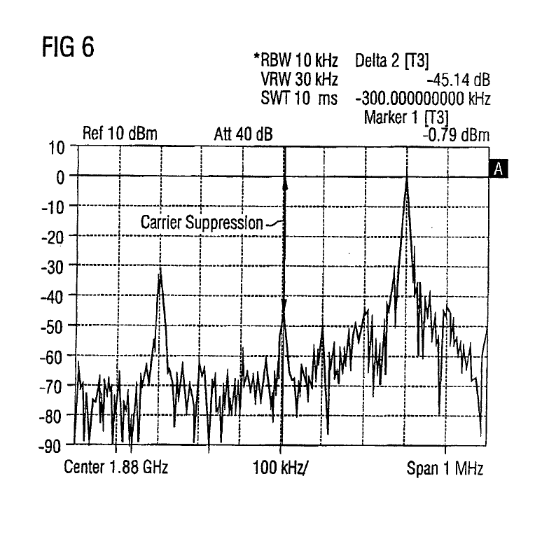

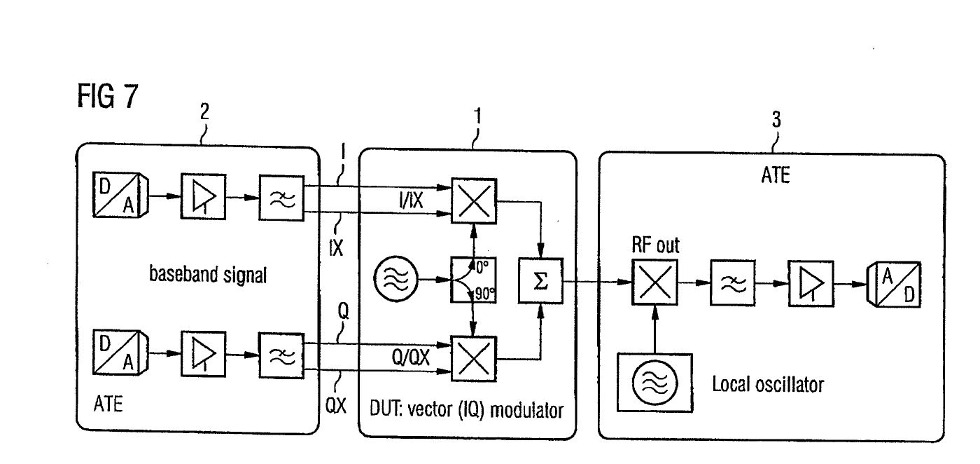

For comparison purposes, FIG. 6 shows the output signal from a vector modulator after carrying out the method and the compensation for the DC signal elements. In this case, the signal used as the input signal is the same as that which was used in FIG. 2B. In contrast to FIG. 2, in which the residual carrier was only about 23 dB below the desired signal, a carrier suppression of about 45 dB is achieved in FIG. 6.

An advantage of this method is its relatively high speed, since it is sufficient to measure the power of the carrier signal for a total of four different signals within a short time. The method can be suitable for automatic test systems used in production. One such test system is illustrated schematically in FIG. 7.

A vector modulator DUT (Device Under Test) to be tested in this case is arranged between two areas 2 and 3 of a test system ATE. As is illustrated schematically here, the area 2 produces a baseband signal with an in-phase component and a quadrature component. The in-phase component and the quadrature component are respectively in the form of difference signals I/IX and Q/QX, since the vector modulator 1is designed to process difference signals. The area 3 of the test system ATE receives the output signal from the vector modulator 1, and converts it back to an intermediate frequency, by means of a local oscillator. The received and converted signal is first of all filtered, amplified, and is then converted to a digital signal for further signal processing. The method can also be carried out in a simple manner with the existing test systems, such as that illustrated in FIG. 7.

For this purpose, the area 2 generates a signal for the in-phase component with the value +I or −I throughout the first two time periods, where I is a defined constant amplitude. This results in a positive polarity for the difference signal I/IX for the path I of the difference signal throughout the first time period T1, and a negative polarity for the difference signal IX. The two polarities change during the time period T2.

The vector modulator converts the in-phase component and uses it to produce an output signal, which is analyzed in the area 3 of the ATE test system. The method is repeated with a signal for the quadrature component in the next two time periods. The DC signal element for the in-phase component and for the quadrature component of the vector modulator is calculated from the signal emitted from the vector modulator. This makes it possible to compensate for DC signal elements in the vector modulator.

This concept can be extended. For example, it is also at any time possible to compensate for the DC signal elements which occur within the baseband signal processing and are likewise converted to a residual carrier by the vector modulator. The further circuit elements are connected upstream of the vector modulator 1 for this purpose. As a result, the method produces only one signal at the frequency of the carrier signal. This is known and is a result of the local oscillator signal that is used. If converted higher-order elements are suitably suppressed, there is no longer any need to measure the power of the carrier signal by means of a frequency-selective spectrum analyzer, and a simple power measurement device can be used instead, which is non-specific in frequency terms. However, in contrast to a spectrum analyzer or network analyzer, a power measurement device such as this allows high-precision absolute power measurements. It is thus feasible to provide a power measurement diode within an arrangement which contains the vector modulator, in order in this way to also make it possible to carry out a retrospective calibration during operation in a telecommunications appliance. This likewise makes it possible to compensate for external parameters which cause DC signals.

The method according to the invention thus measures the power or the amplitude of an output signal which has been produced by a vector modulator. For this purpose, a constant signal is applied successively for a specific time period to the inputs of the vector modulator. The vector modulator produces an output signal at a constant input signal level and at the frequency of the local oscillator signal. Only four measurements are required to determine a DC signal element. The value of the offset element can be determined from this. The type of calculation described here is, however, only one of a large number of options for determination of the undesirable DC signal element from the powers or signal amplitudes determined in the time periods. By way of example, the reciprocal of the fraction in formula 4 can also be used for calculation purposes.

Furthermore, the method according to the invention also makes it possible to compensate for non-linear signal elements which are caused by signals with a different input amplitude. This is possible as a result of the use of input signals which are constant in certain time periods but have different amplitudes. Arrangements with vector modulators can thus be designed so as to allow calibration by means of the method according to the invention even at a later time.

Although the invention has been shown and described with respect to a certain aspect or various aspects, it is obvious that equivalent alterations and modifications will occur to others skilled in the art upon the reading and understanding of this specification and the annexed drawings. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several aspects of the invention, such feature may be combined with one or more other features of the other aspects as may be desired and advantageous for any given or particular application. Furthermore, to the extent that the term “includes” is used in either the detailed description or the claims, such term is intended to be inclusive in a manner similar to the term “comprising.”

### List of Reference Symbols

I: In-phase component
Q: Quadrature component
Carrier Suppression: Residual carrier suppression
1: Vector modulator
2, 3: Areas of a test system
S1, S2: Sine-wave signals
T1, T2, T3, T4: Time periods

1. A method for residual carrier suppression comprising:
providing an arrangement comprising a vector modulator, wherein the vector modulator converts a baseband signal comprising an in-phase component and a quadrature component to a complex output signal;
supplying the arrangement with a component of the baseband signal as a first signal at a constant level and with a first polarity during a first time period;
determining a first average signal amplitude of the output signal from the first signal;
supplying the arrangement with the component of the baseband signal as a second signal at a constant level with a second polarity during a second time period;
determining a second average signal amplitude of the output signal from the second signal;
determining an offset value according to the first average signal amplitude and the second average signal amplitude of the output signal; and
adjusting the component of the baseband signal according to the determined offset value.

2. The method of claim 1, wherein determining the offset value comprises forming a difference between the first average signal amplitude and the second average signal amplitude.

3. The method of claim 1, wherein the determination of the offset value comprises multiplication of the value of the difference between the first average signal amplitude and the second average signal amplitude by a reciprocal of a sum of the first average signal amplitude and the second average signal amplitude.

4. The method of claim 1, wherein supplying the component as a second signal further comprises supplying the component as a second signal having a different amplitude than the first signal.

5. The method of claim 1, further comprising:
supplying the arrangement with a second component of the baseband signal as a third signal at a constant level and with a third polarity during the first time period;
determining a third average signal amplitude of the output signal from the third signal;
supplying the arrangement with the second component of the baseband signal as a fourth signal at a constant level with a fourth polarity during a second time period;
determining a fourth average signal amplitude of the output signal from the fourth signal; and
wherein determining the offset value is determined according to the first average signal amplitude, the second average signal amplitude, the third average signal amplitude, and the fourth average signal amplitude.

6. The method of claim 5, wherein determining the offset value further comprises determining a quotient from a sum of the first average signal amplitude and the second average signal amplitude and a sum of the third average signal amplitude and the fourth average signal amplitude.

7. The method of claim 1, wherein the first signal is supplied by forming a difference signal at a constant level.

8. The method of claim 1, wherein the first average signal amplitude is determined as an average power of a carrier signal.

9. The method of claim 1, wherein determining the first average signal amplitude and the second average signal amplitude from the output signal employ a spectrum analyzer.

10. The method of claim 1, wherein determining the first average signal amplitude and the second average signal amplitude from the output signal employ a power measurement device.

11. The method of claim 1, wherein determining the first average signal amplitude and the second average signal amplitude from the output signal employ a diode.

12. A method for residual carrier suppression comprising:
obtaining a first component of a baseband signal;
measuring a first average power of the first component over a first time period;
measuring a second average power of the first component over a second time period; and
computing a first DC signal element that represents distortion attributed to the first component according to the first average power and the second average power.

13. The method of claim 12, further comprising:
obtaining a second component of the baseband signal;
measuring a third average power of the second component over a third time period;
measuring a fourth average power of the second component over a fourth time period; and
computing a second DC signal element that represents distortion attributed to the second component according to the third average power and the fourth average power.

14. The method of claim 13, wherein the first DC signal element is computed as an average power over the first and second time periods and the second DC signal element is computed as an average power over the third and fourth time periods.

15. The method of claim 13, further comprising compensating an output signal generated by vector modulation from the baseband signal according to the first DC signal element and the second DC signal element.

16. The method of claim 13, further comprising determining a ratio of gain of the first component to the second component as a sum of the first measured average power and the second measured average power over a sum of the third measured average power and the fourth measured average power.

17. The method of claim 16, further comprising compensating an output signal generated by vector modulation from the baseband signal according to the ratio of gain of the first component to the second component.

18. The method of claim 12, wherein the first component is an in-phase component.

19. The method of claim 12, wherein the first component is a quadrature component.

20. The method of claim 12, wherein the first component is an in phase component and the second component is a quadrature component.
